(19) United States
(12) Patent Application Publication
(10) Pub. No.: US 2025/0052782 A1
(43) Pub. Date: Feb. 13, 2025

(54) INSPECTION SOCKET

(71) Applicant: YOKOWO CO., LTD., Tokyo (JP)

(72) Inventors: Hirotaka TAKAHASHI, Gunma (JP); Takahiro MAEDA, Gunma (JP); Takayoshi OKUNO, Gunma (JP); Masataka MIYAGAWA, Gunma (JP)

(73) Assignee: YOKOWO CO., LTD., Tokyo (JP)

(21) Appl. No.: 18/797,604

(22) Filed: Aug. 8, 2024

(30) Foreign Application Priority Data
Aug. 9, 2023 (JP) 2023-130172

(51) Int. Cl. G01R 1/04; G01R 1/067

(52) U.S. Cl. CPC G01R 1/0466; G01R 1/0458; G01R 1/06722

(57) ABSTRACT

An inspection socket including: a contact probe; a pin block having a through hole for accommodating the contact probe; and a heat dissipator located on an internal side in the through hole in a through direction of the through hole between the pin block and the contact probe and having an electrical insulating property for transmitting heat from the contact probe to the pin block.

### CROSS-REFERENCE TO RELATED APPLICATION(S)

This application is based on and claims priority under 35 USC 119 from Japanese Patent Application No. 2023-130172 filed on Aug. 9, 2023, the contents of which are incorporated herein by reference.

### TECHNICAL FIELD

The present invention relates to an inspection socket.

### BACKGROUND ART

In order to inspect electrical characteristics of a semiconductor integrated circuit, there is known an inspection socket in which an external contact electrode of a semiconductor integrated circuit is energized to perform an inspection.

Patent Literatures 1 and 2 disclose such inspection sockets.

### CITATION LIST

### Patent Literature

Patent Literature 1: JP2005-156530EA
Patent Literature 2: JP2018-179671A

### SUMMARY

One object of the present invention is to provide an inspection socket capable of allowing a large current to flow during an energization inspection of a semiconductor integrated circuit. Other objects of the present invention will become apparent from the description of the present specification.

An aspect of the present invention is an inspection socket including: a contact probe; a pin block having a through hole for accommodating the contact probe; and a heat dissipator located on an internal side in the through hole in a through direction of the through hole between the pin block and the contact probe and having an electrical insulating property for transmitting heat from the contact probe to the pin block.

### BRIEF DESCRIPTION OF DRAWINGS

FIG. 1 is a schematic view of an embodiment of an inspection socket.

FIG. 2 is a schematic view of an embodiment of a contact probe.

FIG. 3A is a schematic view illustrating a positional relation between a contact probe and a pin block in a socket in the related art.

FIG. 3B is a schematic view illustrating a positional relation among a contact probe, a pin block, and a heat dissipator in the embodiment of the inspection socket.

FIG. 4A is a schematic view illustrating an embodiment of an inspection socket including a power supply probe, a ground probe, and a signal probe.

FIG. 4B is a cross-sectional view of the heat dissipator illustrated in FIG. 4A.

FIG. 5 is a schematic view illustrating another embodiment of the inspection socket including the power supply probe, the ground probe, and the signal probe.

### DESCRIPTION OF EMBODIMENTS

The present invention will be specifically described with reference to the following embodiments, but the present invention is not limited thereto. When there is no particular reference to each configuration and manufacturing method thereof in the present specification, those skilled in the art can use a well-known technology in this field. Each embodiment can be combined based on ordinary knowledge by those skilled in the art. Configurations not specifically described in the respective embodiments can have configurations similar to those of other embodiments or configurations suitable for the embodiments. Further, the dimensions illustrated in the figures are drawn differently from actual dimensions and dimensional ratios for ease of view. In the present specification, the “upper” refers to a side on which an inspection target is located, and the “lower” refers to a side on which an inspection circuit is located.

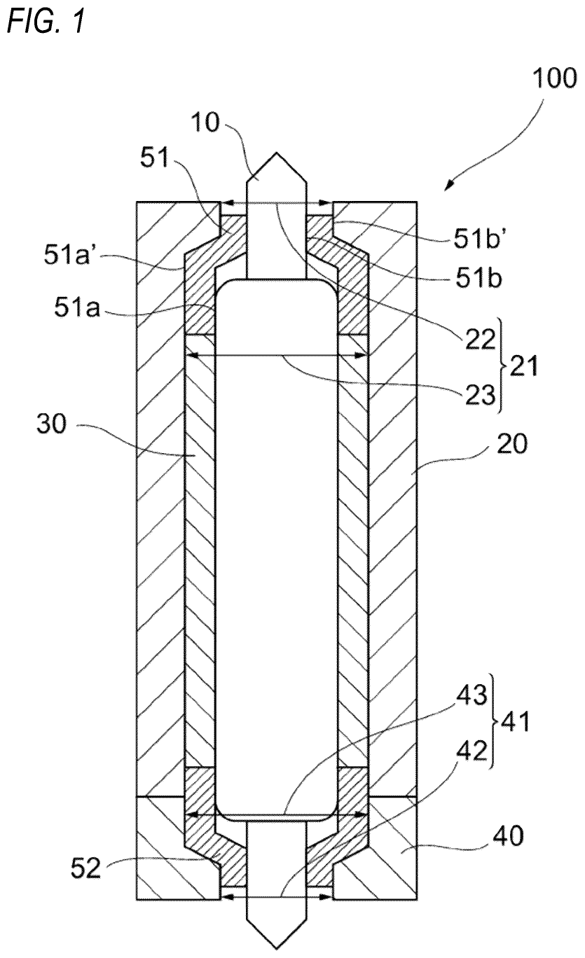

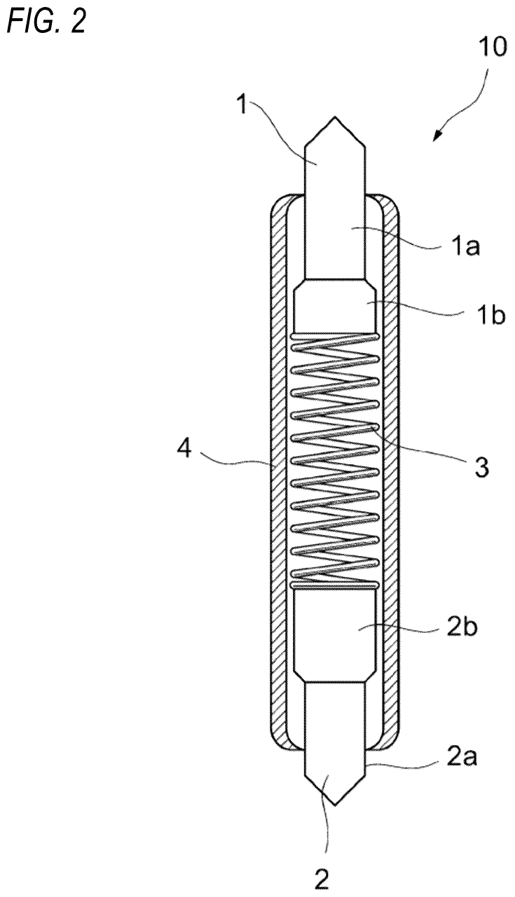

FIG. 1 is a schematic view of an embodiment of an inspection socket 100. FIG. 2 is a schematic view of an embodiment of a contact probe 10.

The inspection socket 100 illustrated in FIG. 1 includes the contact probe 10, a pin block 20, a heat dissipator 30, a pin plate 40, an upper electrical insulator 51, and a lower electrical insulator 52. The pin block 20 is made of a metal and has a through hole 21 for accommodating the contact probe 10. The heat dissipator 30 has an electrical insulating property, is located on an internal side in the through hole 21 in a through direction of the through hole 21 between the pin block 20 and the contact probe 10, and transmits heat from the contact probe 10 to the pin block 20. The pin plate 40 is made of a metal and is located at a lower portion of the pin block 20. The upper electrical insulator 51 prevents electrical connection between the contact probe 10 and the pin block 20. The lower electrical insulator 52 prevents electrical connection between the contact probe 10 and the pin plate 40. The upper electrical insulator 51 and the lower electrical insulator 52 are members each having an electrical insulating property, and may be collectively referred to as an electrical insulator 50.

The contact probe 10 illustrated in FIG. 2 includes an upper plunger 1, a lower plunger 2, a spring 3, and a cylindrical body 4 surrounding the upper plunger 1, the lower plunger 2, and the spring 3. The upper plunger 1 brings the contact probe 10 into contact with the inspection target, and the lower plunger 2 brings the contact probe 10 into contact with the inspection circuit. Thus, the inspection target and the inspection circuit are electrically connected to each other via the upper plunger 1, the cylindrical body 4, the spring 3, and the lower plunger 2. In FIG. 2, in order to illustrate an internal structure of the contact probe 10, only a cross section of the cylindrical body 4 is illustrated.

It has been found that an elastic operating performance of the contact probe 10 is reduced when a large current is caused to flow through an inspection target such as a semiconductor integrated circuit. When the cause was analyzed, it was found that the contact probe 10 was too high in temperature due to Joule heat, and in particular, the spring 3 was too high in temperature. In order to prevent the contact probe 10 from becoming too high in temperature, the present inventors have studied various materials and the like of each component of the contact probe 10. The present inventors have found that it is extremely effective to use the heat dissipator 30 having an electrical insulating property for transmitting heat from the contact probe 10 to the pin block 20 in consideration of various studies.

Only a slight gap of about 0.1 mm to 0.3 mm was present between the contact probe 10 and the pin block 20 in a socket in the related art. Therefore, it was not considered that this gap significantly affects the heat transmission between the contact probe 10 and the pin block 20. It was unexpected for the present inventors that effective measures against temperature can be taken only by using the heat dissipator 30 to fill the slight gap.

The contact probe 10 is usually a cylindrical member elongated in an axial direction. The contact probes 10 are usually arranged side by side at a pitch of several hundred microns in the inspection socket 100.

The upper plunger 1 of the contact probe 10 includes a pin-shaped portion 1a and a columnar portion 1b having a diameter larger than that of the pin-shaped portion 1a, and the pin-shaped portion 1a comes into contact with an inspection target, such as an external contact electrode of a semiconductor integrated circuit.

The lower plunger 2 of the contact probe 10 includes a pin-shaped portion 2a and a columnar portion 2b having a diameter larger than that of the pin-shaped portion 2a, and the pin-shaped portion 2a comes into contact with an inspection circuit. Thus, the inspection target and the inspection circuit are electrically connected to each other via the contact probe 10. The inspection circuit is a well-known element in the present field, and can generate a signal to be supplied to the inspection target in order to inspect electrical characteristics of the inspection target.

The spring 3 of the contact probe 10 is formed from a coil spring formed of piano wire or stainless steel wire. The spring 3 is located between the upper plunger 1 and the lower plunger 2, and biases the upper plunger 1 and the lower plunger 2 in a direction away from each other. Due to the elastic property of the spring 3, the upper plunger 1 and the lower plunger 2 can be brought into contact with each other without applying excessive force to the inspection target and the inspection circuit.

The cylindrical body 4 of the contact probe 10 is a cylindrical body in which at least one end is open, and is made of a conductive material. The cylindrical body 4 may be made of a metal material such as beryllium copper, or may be further plated with gold or the like. The cylindrical body 4 surrounds the upper plunger 1, the lower plunger 2, and the spring 3 by at least partially surrounding the upper plunger 1, the lower plunger 2, and the spring 3 from the outside in a circumferential direction. Opening ends at both ends of the cylindrical body 4 are bent inward to form locking portions, thereby preventing the upper plunger 1 and the lower plunger 2 from coming off from the cylindrical body 4. The cylindrical body 4 of the contact probe 10 may be fixed to one of the upper plunger 1 and the lower plunger 2, and may be closed on the fixed side and opened at the unfixed side, or the cylindrical body 4 may be opened at both ends as illustrated in FIG. 2.

The cylindrical body 4 has an inner diameter larger than diameters of the upper plunger 1, the lower plunger 2, and the spring 3 so as to surround the upper plunger 1, the lower plunger 2, and the spring 3. The inner diameter of the cylindrical body 4 is, for example, in a range of 250 μm to 260 μm. An outer diameter of the cylindrical body 4 may be an outer diameter of the contact probe 10, and is, for example, in a range of 320 μm to 330 μm. A difference between the inner diameter and the outer diameter of the cylindrical body 4, that is, a thickness of the cylindrical body 4 is, for example, in a range of 60 μm to 80 μm.

The pin block 20 has a through hole 21 for accommodating the contact probe 10. The through hole 21 is a stepped hole including a large-diameter hole 23 having a diameter larger than the outer diameter of the contact probe 10 and including a small-diameter hole 22 at an upper opening portion. A large number of through holes 21 can be arranged at a pitch of several hundred microns corresponding to a large number of arrangement of the contact probes 10. In the present specification, the “through direction of the through hole” refers to a direction along the axial direction of the contact probe 10, and the axial direction of the contact probe 10 and the through direction of the through hole can be coaxial with each other.

In the embodiment illustrated in FIG. 1, the pin block 20 is made of a metal, but the material for the pin block 20 can be changed depending on the purpose of the inspection socket 100. For example, the pin block 20 may be made of an electrical insulating material such as a resin. However, when a high frequency signal is used during an inspection, the pin block 20 is preferably made of an electrical conductive material such as a metal. This is because the contact probe 10 and the pin block 20 can be considered to have a configuration similar to a coaxial cable, and when a high frequency signal is provided by the contact probe 10 serving as an inner conductor, a shielding effect is provided by the pin block serving as an outer conductor.

In a case in which the pin block 20 is made of an electrical conductive material, it is preferable to dispose the upper electrical insulator 51 between the upper plunger 1 of the contact probe 10 and the pin block 20 in order to prevent electrical connection between the contact probe 10 and the pin block 20. On the other hand, in a case in which the pin block 20 is made of an electrical insulating material, the upper electrical insulator 51 is not required.

The heat dissipator 30 is located on the internal side in the through hole 21 in the through direction of the through hole 21 between the pin block 20 and the contact probe 10. Here, the portion “located on the internal side in the through hole” refers to a portion inside the through hole 21 of the pin block 20 other than the vicinity of the openings of the through hole 21, and refers to, for example, a portion where the large-diameter hole 23 is formed in the through hole 21. In the embodiment in which the pin plate 40 is present, the portion “located on the internal side in the through hole” refers to a portion in a pin plate-side through hole 41 of the pin plate 40 other than the vicinity of an opening of the pin plate-side through hole 41 in addition to the portion described above, and also refers to, for example, a portion where a large-diameter hole 43 in the pin plate-side through hole 41 is formed. It is sufficient that the heat dissipator 30 is located along at least a part of the length of the through hole 21 in the through direction. A shape of the heat dissipator 30 is not particularly limited, but in a case in which the heat dissipator 30 has a tube shape surrounding the periphery of the contact probe 10, heat from the contact probe 10 can be effectively transmitted to the pin block 20, which is preferable. Although it is preferable that the heat dissipator 30 surrounds the contact probe 10 as much as possible in the circumferential and axial directions, it is unnecessary to surround the entire contact probe 10.

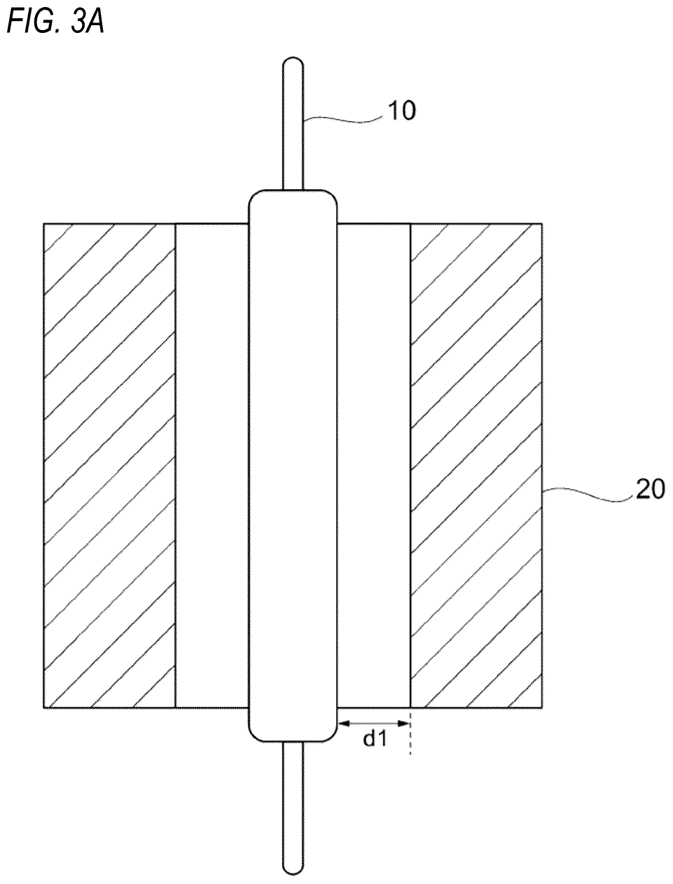

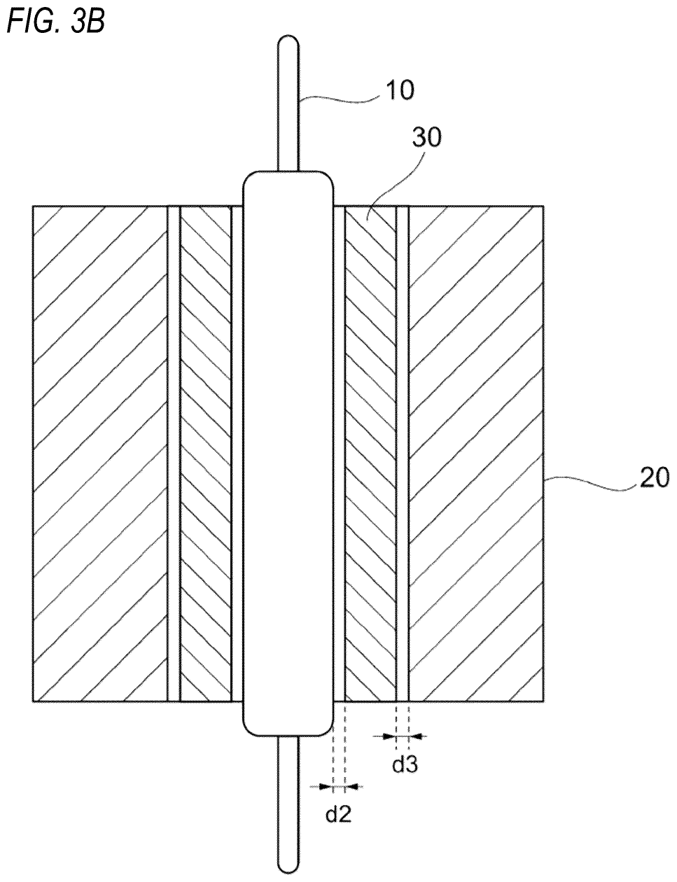

In a case in which the heat dissipator has a tube shape or the like, a difference between an inner diameter and an outer diameter of the heat dissipator, that is, a thickness of the heat dissipator may be, for example, 30 μm or more, 50 μm or more, 70 μm or more, 80 μm or more, or 100 μm or more, 200 μm or less, 150 μm or less, 120 μm or less, 100 μm or less, or 80 μm or less. The thickness of the heat dissipator is, for example, in a range of 30 μm or more and 200 μm or less, or 50 μm or more and 120 μm or less. The inner diameter of the heat dissipator can be calculated based on a gap d2 between the outer diameter of the contact probe 10 and the inner diameter of the heat dissipator 30 described below with reference to FIG. 3B.

The heat dissipator 30 is a member having an electrical insulating property to prevent electrical connection between the contact probe 10 and the pin block 20. Meanwhile, the heat dissipator 30 is not particularly limited as long as it is configured to enhance the heat conductivity and the heat transmission property from the contact probe 10 to the pin block 20. The heat dissipator 30 preferably has, for example, heat resistance of 200° C. or higher. The heat dissipator 30 may be, for example, a ceramic such as silica, alumina, zirconia, barium titanate, silicon carbide, silicon nitride, or aluminum nitride. The heat dissipator 30 may contain an electrical conductive material having an electrical insulating layer on a surface thereof, and examples of the electrical insulating layer include, in addition to a ceramic layer, a resin layer such as a fluorine-based resin, polyphenylene sulfide, and polyimide, in particular, a resin coating layer. Examples of the electrical conductive material include, but are not limited to, metals, for example, copper-based metals such as beryllium copper.

The heat dissipator 30 may be disposed inside the through hole 21 of the pin block 20 without being supported by another member. For example, in the case of the embodiment illustrated in FIG. 1, such a configuration can be obtained by forming or disposing the upper electrical insulator 51 in the through hole 21 of the pin block 20, disposing the contact probe 10 and the heat dissipator 30 next, and fixing the pin plate 40 in which the lower electrical insulator 52 is formed or disposed to the pin block 20.

The upper electrical insulator 51 is insulating with a resin or the like as a material, and formed in a surrounding shape. As illustrated in FIG. 1, on an inner side of the upper electrical insulator 51, a large-diameter inner peripheral portion 51a that accommodates an end portion of the cylindrical body 4 of the contact probe 10 is formed, and a small-diameter inner peripheral portion 51b through which the upper plunger 1 of the contact probe 10 is inserted is formed. On an outer side of the upper electrical insulator 51, a large-diameter outer peripheral portion 51a′ having the same diameter as the large-diameter hole of the through hole 21 of the pin block 20 is formed, and a small-diameter outer peripheral portion 51b′ fitted into the small-diameter hole 22 of the through hole 21 is formed. Accordingly, the upper electrical insulator 51 does not come out of the pin block 20. The lower electrical insulator 52 has the same configuration as the upper electrical insulator 51 with respect to the plate-side through hole 41.

FIG. 3A is a schematic view illustrating a positional relation between the contact probe 10 and the pin block 20 in a socket in the related art. FIG. 3B is a schematic view illustrating a positional relation among the contact probe 10, the pin block 20, and the heat dissipator 30 in the present embodiment.

In FIGS. 3A and 3B, the diameter of the contact probe 10 is, for example, about 300 μm, and the diameter (the inner diameter) of the through hole 21 of the pin block 20 in which the contact probe 10 is accommodated is, for example, about 750 μm. Therefore, as illustrated in FIG. 3A, a gap d1 between the contact probe 10 and the pin block 20 is, for example, about 200 μm.

With respect to this, the gap d2 formed by the outer diameter of the contact probe 10 and the inner diameter of the heat dissipator 30, and a gap d3 formed by the inner diameter of the pin block 20 and the outer diameter of the heat dissipator 30, which are illustrated in FIG. 3B, may be 50 μm or less, 30 μm or less, 20 μm or less, 10 μm or less, or 5 μm or less on average, respectively. It is preferable that each of the gap d2 and the gap d3 is not present from the viewpoint of heat conduction and heat transmission, but each of the gap d2 and the gap d3 may be 1 μm or more, 3 μm or more, 5 μm or more, or 10 μm or more from the viewpoint of ensuring a manufacturing tolerance of each member and facilitating the manufacture of the inspection probe. The gap d2 and the gap d3 may be, for example, 1 μm or more and 30 μm or less, or 3 μm or more and 10 μm or less.

The pin plate 40 is located at a lower portion of the pin block 20 and is fixed vertically to the pin block 20. The pin plate 40 includes a plate-side through hole 41 at a position communicating with the through hole 21 of the pin block 20, and holds the contact probe 10 by exposing one end of the contact probe 10. The plate-side through hole 41 is a stepped hole including a large-diameter hole 43 having a diameter larger than the outer diameter of the contact probe 10 and including a small-diameter hole 42 at a lower opening portion.

In the embodiment illustrated in FIG. 1, the pin block 20 is made of a metal, but the material for the pin block 20 can be changed depending on the purpose of the inspection socket 100. The pin plate 40 may also be made of an electrical insulating material such as a resin, but is preferably made of an electrical conductive material such as a metal in a case in which a high frequency signal is used during an inspection. Compared with a case in which only the pin block 20 is made of a metal, in a case in which both the pin block 20 and the pin plate 40 are made of a metal, a higher shielding effect can be obtained, and thus a configuration better in high frequency characteristics can be obtained.

In a case in which the pin plate 40 is made of an electrical conductive material, it is preferable to dispose the lower electrical insulator 52 between the lower plunger 2 of the contact probe 10 and the pin plate 40 in order to prevent electrical connection between the contact probe 10 and the pin plate 40. On the other hand, in a case in which the pin plate 40 is made of an electrical insulating material, the lower electrical insulator 52 is not required.

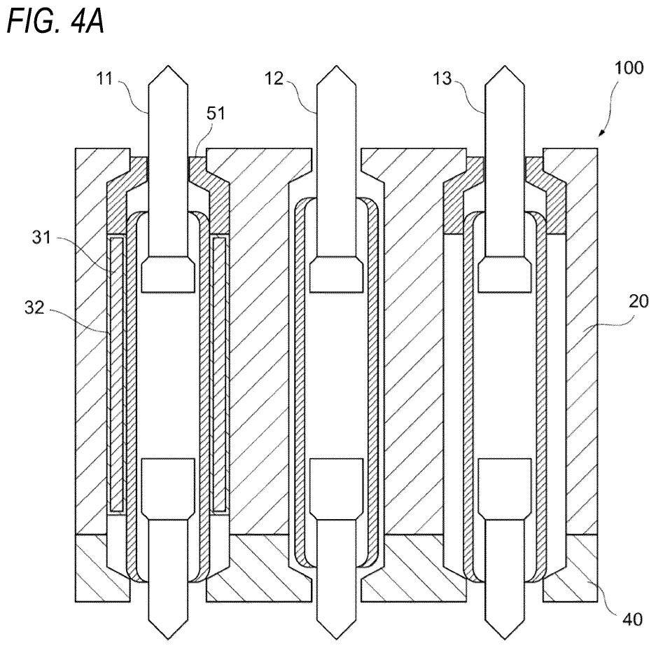

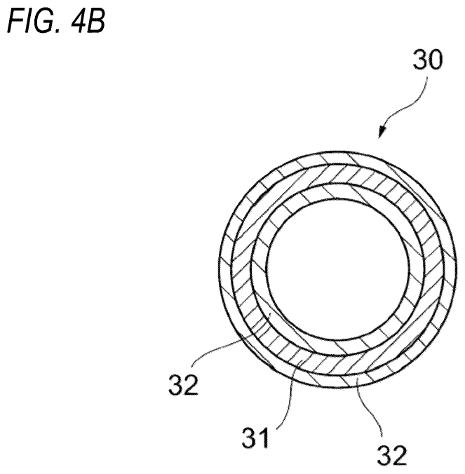

FIG. 4A illustrates an embodiment in which the inspection socket 100 includes a power supply probe 11, a ground probe 12, and a signal probe 13 as the contact probe 10. Since the power supply probe 11 may reach a high temperature due to a flow of a large current, the heat dissipator 30 is located between the power supply probe 11 and the pin block 20. On the other hand, as illustrated in this embodiment, the heat dissipator 30 may be not present between the ground probe 12 and the signal probe 13 and the pin block 20.

In this embodiment, since the pin plate 40 is made of a resin having an electrical insulating property, the lower electrical insulator 52 is not present between each probe and the pin plate 40. On the other hand, since the pin block 20 is made of a metal having electrical conductivity, the upper electrical insulator 51 for preventing electrical connection between the power supply probe 11 and the signal probe 13 and the pin block 20 is disposed. Since the ground probe 12 may be electrically connected to the pin block 20, the upper electrical insulator 51 is not disposed between the ground probe 12 and the pin block 20.

FIG. 4B is a cross-sectional view of the heat dissipator 30 illustrated in FIG. 4A. In this embodiment, the heat dissipator 30 includes a tube-shaped metal 31 and an electrical insulating layer 32 formed on a surface of the tube-shaped metal 31. In this embodiment, the electrical insulating layer 32 is formed on both an inner surface and an outer surface of the tube-shaped metal 31, but the electrical insulating layer 32 only needs to be formed on either the inner surface or the outer surface of the tube-shaped metal 31.

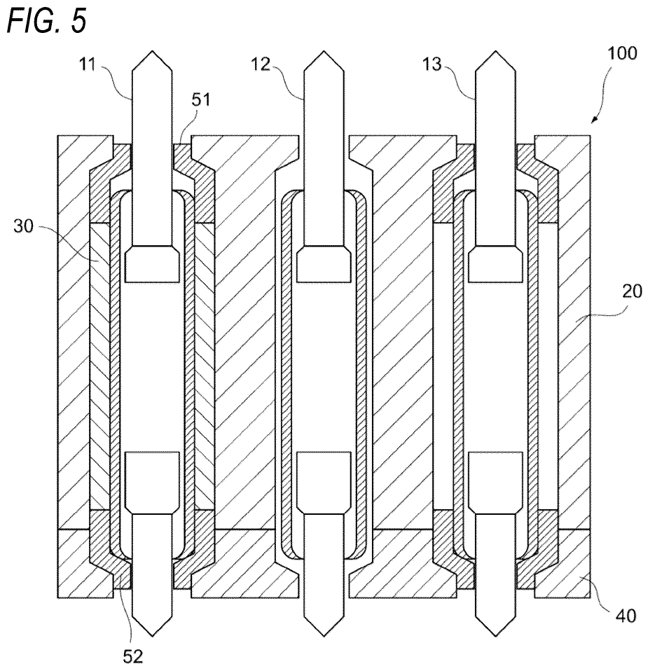

FIG. 5 illustrates an embodiment the same as the embodiment illustrated in FIG. 4A except that the pin plate 40 is made of a metal and the heat dissipator 30 is made of a ceramic. Since the pin plate 40 is made of a metal, in the embodiment illustrated in FIG. 5, in addition to the upper electrical insulator 51 between the power supply probe 11 and the signal probe 13 and the pin block 20, the lower electrical insulator 52 for preventing the electrical connection is disposed between the pin plate 40 and the pin block 20.

### EXAMPLES

A polyimide was coated on an inner surface and an outer surface of a tube-shaped beryllium copper electrodeposition coating to produce a heat dissipator.

Six contact probes were respectively inserted into six adjacent through holes of the pin block including an upper insulator. The produced tube-shaped heat dissipator was inserted into the through holes in a manner of covering the contact probe. Thereafter, the heat dissipator was fixed by a pin plate to produce an inspection socket according to the example. An inspection socket according to a comparative example was produced in the same manner without using the heat dissipator.

In this experiment, a device was produced which is capable of simultaneously applying a current by connecting a lower energization substrate and an upper energization substrate in a manner that the six contact probes are connected in series instead of connecting the inspection circuit and the external contact electrode of the semiconductor integrated circuit to the inspection socket. Accordingly, the temperature can be measured by causing a large current to flow through the contact probe.

Maximum temperatures of the probes of the inspection sockets according to the example and the comparative example when temperatures were constant by increasing currents applied to the contact probe at room temperature were measured by a thermograph. As a result, maximum temperatures as described in the following table were measured with respect to the same standard current value.

TABLE 1

| | | |
|---|---|---|
| Standard current value | Example | Comparative example |

| | | | |
|---|---|---|---|
| 1.0 | 42.3° | C. | 49.2° C. |
| 2.0 | 86.4° | C. | 107.3° C. |
| 3.0 | 146.2° | C. | 179.8° C. |
| 3.5 | 175.7° | C. | 216.9° C. |
| 4.0 | 207.2° | C. | 244.3° C. |

As described above, in the comparative example in which no heat dissipator was used when a current of 1.0 magnitude was applied, the temperature was increased to 49.2° C., and meanwhile, when the same current was applied, the temperature could be controlled to 42.3° C. in the example in which the heat dissipator was used. When a current of 4.0 times was applied, the temperature was increased to 244.3° C. in the inspection socket according to the comparative example, and the contact probe was heated to a level at which the elastic operation was affected. With respect to this, the inspection socket according to the example in which the same current was applied could be controlled to 207.2° C. When the standard current value of 3.5 times was caused to flow, a temperature difference between the example and the comparative example was largest, and the temperature of the inspection socket according to the example was 41.2° C. Since the elastic operation of the contact probe may be affected at about 200° C., it is advantageous to increase the temperature difference at about 200° C.

Next, a tube-shaped first heat dissipator made of aluminum nitride was produced as a heat dissipator. A second heat dissipator was produced by subjecting a surface of a tube-shaped copper (C3604) to a treatment to achieve an electrical insulating property.

The second heat dissipator was set together with the contact probe in the pin block, and a current was applied to one probe. In the same manner, a current was applied to one probe without using a heat dissipator.

As a result, a maximum temperature of the probe when the standard current value was applied at 4.05 times to the experimental apparatus in which the heat dissipator was used was substantially the same as a temperature when the standard current value was applied at 3.13 times to the experimental apparatus in which no heat dissipator was used.

Accordingly, it was confirmed that in a case in which the heat dissipator was used, the temperature was less likely to be high even when a larger current was caused to flow. This also applies to a case in which the first heat dissipator was used.

According to the present specification, an inspection socket according to the following aspects is provided.

### Aspect 1

According to Aspect 1, there is provided an inspection socket 100 including: a contact probe 10; a pin block 20 having a through hole 21 for accommodating the contact probe 10; and a heat dissipator 30 located on an internal side in the through hole 21 in a through direction of the through hole 21 between the pin block 20 and the contact probe 10 and having an electrical insulating property for transmitting heat from the contact probe 10 to the pin block 20.

According to the aspect described above, since the heat dissipator 30 is used, it is possible to prevent the contact probe 10 from becoming too high in temperature even if a large current is caused to flow through the contact probe 10. Accordingly, it is possible to prevent the performance of the contact probe 10 from being deteriorated, and thus it is possible to inspect an inspection target by causing a large current to flow through the contact probe 10. As the performance of the semiconductor integrated circuit is higher, it is necessary to perform the inspection by causing a large current to flow, and thus the inspection socket 100 according to the aspect is extremely advantageous in view of the future higher performance of the semiconductor integrated circuit.

### Aspect 2

In Aspect 2, the heat dissipator 30 has a tube shape surrounding the contact probe.

According to the aspect described above, the heat dissipator 30 can effectively transmit heat from the contact probe 10 to the pin block 20, and thus the heat dissipator 30 has a high heat dissipation property, and a larger current can be caused to flow through the contact probe 10 to inspect the inspection target.

### Aspect 3

In Aspect 3, the heat dissipator 30 contains a ceramic, or a metal having an electrical insulating layer on a surface thereof.

According to the aspect described above, the ceramic or the metal having an electrical insulating layer on a surface thereof can achieve both high heat transmission property and electrical insulating property, and thus the heat dissipator 30 has a high heat dissipation property, and a larger current can be caused to flow through the contact probe 10 to inspect the inspection target.

### Aspect 4

In Aspect 4, a gap between the heat dissipator 30 and the contact probe 10 or a gap between the heat dissipator 30 and the pin block 20 is 50 μm or less on average.

According to the aspect described above, since heat is easily transmitted from the contact probe 10 to the pin block 20, the inspection socket 100 can have high heat dissipation, and a larger current can be caused to flow through the contact probe 10 to inspect the inspection target.

### Aspect 5

In Aspect 5, the contact probe 10 includes an upper plunger 1 connected to an inspection target, a lower plunger 2 connected to an inspection circuit, a spring 3 located between the upper plunger 1 and the lower plunger 2, and a cylindrical body 4 surrounding the upper plunger 1, the lower plunger 2, and the spring 3.

According to the aspect described above, a configuration of the contact probe 10 is specified.

### Aspect 6

In Aspect 6, the inspection socket 100 further includes an electrical insulator 50 between the upper plunger 1 and the pin block 20.

According to the aspect described above, even if the pin block 20 is made of a metal, electrical insulation between the upper plunger 1 and the pin block 20 can be easily achieved.

### Aspect 7

In Aspect 7, the inspection socket 100 further includes a pin plate 40 at a lower portion of the pin block 20; and an electrical insulator 50 between the lower plunger 2 and the pin plate 40.

According to the aspect described above, even if the pin plate 40 is made of a metal, electrical insulation between the lower plunger 2 and the pin block 20 can be easily achieved.

### Aspect 8

In Aspect 8, the contact probe 10 includes a power supply probe 11, a ground probe 12, and a signal probe 13, and the heat dissipator 30 is located between the power supply probe 11 and the pin block 20.

According to the aspect described above, the heat generated in the power supply probe 11 can be effectively transmitted to the pin block 20.

1. An inspection socket comprising:
a contact probe;
a pin block having a through hole for accommodating the contact probe; and
a heat dissipator located on an internal side in the through hole in a through direction of the through hole between the pin block and the contact probe and having an electrical insulating property for transmitting heat from the contact probe to the pin block.

2. The inspection socket according to claim 1, wherein
the heat dissipator has a tube shape surrounding the contact probe.

3. The inspection socket according to claim 1, wherein
the heat dissipator contains a ceramic, or a metal having an electrical insulating layer on a surface thereof.

4. The inspection socket according to claim 1, wherein
a gap between the heat dissipator and the contact probe or a gap between the heat dissipator and the pin block is 50 μm or less on average.

5. The inspection socket according to claim 1, wherein
the contact probe includes an upper plunger connected to an inspection target, a lower plunger connected to an inspection circuit, a spring located between the upper plunger and the lower plunger, and a cylindrical body surrounding the upper plunger, the lower plunger, and the spring.

6. The inspection socket according to claim 5, further comprising:
an upper electrical insulator between the upper plunger and the pin block.

7. The inspection socket according to claim 5, further comprising:
a pin plate at a lower portion of the pin block; and
a lower electrical insulator between the lower plunger and the pin plate.

8. The inspection socket according to claim 1, wherein
the contact probe includes a power supply probe, a ground probe, and a signal probe, and
the heat dissipator is located between the power supply probe and the pin block.
